(19) United States
(12) Patent Application Publication
(10) Pub. No.: US 2017/0336489 A1
(43) Pub. Date: Nov. 23, 2017

(54) MRI METHOD FOR MEASURING VELOCITY PROFILES IN DRILLING MUD

(71) Applicant: ASPECT IMAGING LTD., Shoham (IL)

(72) Inventors: Peter BENDEL, Rishon LeZion (IL); Boaz SHAPIRA, Eshhar (IL)

(73) Assignee: ASPECT IMAGING LTD., Shoham (IL)

(21) Appl. No.: 15/523,228

(22) PCT Filed: Nov. 1, 2015
(86) PCT No.: PCT/IB2015/058444

§ 371 Date: Apr. 28, 2017

Related U.S. Application Data
(60) Provisional application No. 62/074,119, filed on Nov. 3, 2014.

(51) Int. Cl. G01R 33/563; G01R 33/483; G01R 33/48

(52) U.S. Cl. CPC G01R 33/56333; G01R 33/4816; G01R 33/4835

(57) ABSTRACT

An MRI-based method for determining a velocity profile for a fluid flowing through a pipe, said method comprising: selecting a slice through which said fluid is flowing; selecting a pulse sequence; separating said pulse sequence into a preparation part and a readout part; applying said preparation part to said slice; waiting a predetermined time Rt; and, applying said readout part to said slice.

### FIELD OF THE INVENTION

This invention relates to methods for measuring velocity profiles in flows of drilling mud. Specifically, it relates to improved methods that measure the velocity profiles using magnetic resonance imaging (MRI).

### BACKGROUND OF THE INVENTION

In magnetic resonance imaging (MRI) measurements of certain types of drilling mud, most of the signal is lost from the edges of the pipe, where the velocity is low and the shear rate is high. This loss of signal is evident even in simple spin-echo (SE) images, i.e. images that do not have any velocity-encoding gradients. The degree of signal loss shows a positive correlation with echo time and flow rate.

While there is no definitive proof of the cause of this problem, it appears that it is related to internal gradients in the mud, most likely arising from suspending paramagnetic or magnetic particles in the sample. While there is some hope that the problem can be mediated by working at lower magnetic field strengths, there is as yet no way of making a reliable quantitative prediction of the “visibility” of the high shear rate regions at a given field strength.

Thus, finding an efficient MRI method for measuring velocity profiles in drilling mud remains a long-felt but unmet need.

### SUMMARY OF THE INVENTION

It is an object of the present invention to disclose a novel MRI method for measuring velocity profiles in drilling mud. The solution proposed by the present invention is to drastically reduce the echo time by encoding the velocity information into the longitudinal magnetization (M_{z}) rather than into the transverse magnetization. This method obviates the need to lower the magnetic field strength in order to make the requisite measurements.

In some embodiments of the invention, the pulse sequence is separated into a “preparation” part and a “readout” part, which are separated by a variable time. The role of the “preparation” part of the sequence is to create a situation in which the magnetization of the spins of the selected slice is different from that of the inflowing spins. The flow velocity can then be quantified as a function of the temporal evolution of the magnetization in the slice.

It is therefore an object of the present invention to disclose an MRI-based method for determining a velocity profile for a fluid flowing through a pipe, the method comprising: selecting a slice of the pipe through which the fluid is flowing; selecting a pulse sequence comprising a preparation part and a readout part; applying the preparation part to the slice; waiting a predetermined time Rₜ; and applying the readout part to the slice, where the readout part comprising an imaging sequence, wherein the velocity profile is determinable from analysis of the imaging sequence.

In some embodiments of the method, the pulse sequence is a standard Spin Echo sequence. In some embodiments of the invention, the pulse sequence is a very short T_{E} sequence. In some embodiments of the invention, the pulse sequence is a UTE sequence with spiral k-space sampling. In some some embodiments of the invention, the pulse sequence is a UTE sequence with spiral k-space sampling and segmentation.

It is a further object of the present invention to disclose a method as defined in any of the preceding, additionally comprising a step of determining the velocity in at least one volume within the slice according to

$$v = \frac{Fl}{{R}_{t}} ,$$

where F is the fraction of the population of spins that flowed into the slice during the time Rₜ and l is the thickness of the slice.

It is a further object of the present invention to disclose a method as defined in any of the preceding, additionally comprising a step of determining the velocity in at least one volume within the slice according to

$$v = \frac{Fl}{{R}_{t}} and F = 1 - \frac{S}{1 - β e \text{?}} , \\ \text{?} \text{indicates text missing or illegible when filed}$$

where F is the fraction of the population of spins in the slice that flowed into the slice during the time Rₜ, S is a fraction of a population of spins in the slice that resided in the slice for the whole of the recovery time Rₜ and which retain a magnetization imposed upon then during the preparation part, l is the thickness of the slice, β is the magnetization fraction in the slice immediately after the preparation part, and R₁ is the spin-lattice relaxation rate.

It is a further object of the present invention to disclose a method as defined in any of the preceding, additionally comprising the steps of (i) providing N predetermined times (Rₜ), 1≦i≦N, and (ii) for each predetermined time (Rₜ)ᵢ, 1≦i≦N, executing the steps of applying the preparation part, waiting the predetermined time (Rₜ)ᵢ, and applying the readout part.

It is a further object of the present invention to disclose a method as defined in any of the preceding, wherein the pulse sequence provides a longitudinal magnetization and a transverse magnetization, and the method comprises encoding velocity information into the longitudinal magnetization.

It is a further object of the present invention to disclose a method as defined in any of the preceding, additionally comprising a step of applying the method to at least two slices of the fluid in the pipe.

It is a further object of the present invention to disclose a method as defined in any of the preceding, additionally comprising a step of selecting the velocity profile from a group consisting of a 2D profile and a 3D profile.

It is a further object of the present invention to disclose a method as defined in any of the preceding, wherein the fluid comprises drilling mud.

### BRIEF DESCRIPTION OF THE DRAWINGS

The invention will now be described with reference to the drawings, wherein

FIG. 1 presents a schematic flowchart of an exemplary embodiment of an MRI pulse sequence;

FIG. 2 presents a schematic flowchart of an exemplary embodiment of a process for generating a flow velocity profile in a slice of a flowing fluid; and,

FIG. 3 presents a graph comparing results for a flow velocity profile made by the method disclosed herein with results obtained from a conventional method.

### DETAILED DESCRIPTION OF THE PREFERRED EMBODIMENTS

In the following description, various aspects of the invention will be described. For the purposes of explanation, specific details are set forth in order to provide a thorough understanding of the invention. It will be apparent to one skilled in the art that there are other embodiments of the invention that differ in details without affecting the essential nature thereof. Therefore the invention is not limited by that which is illustrated in the figure and described in the specification, but only as indicated in the accompanying claims, with the proper scope determined only by the broadest interpretation of said claims.

The present invention discloses an MRI method for measuring velocity profiles in drilling mud by drastically reducing the echo time by encoding velocity information into the longitudinal magnetization (M_{z}) rather than into the transverse magnetization. This method obviates the need to lower the magnetic field strength in order to make the requisite measurements.

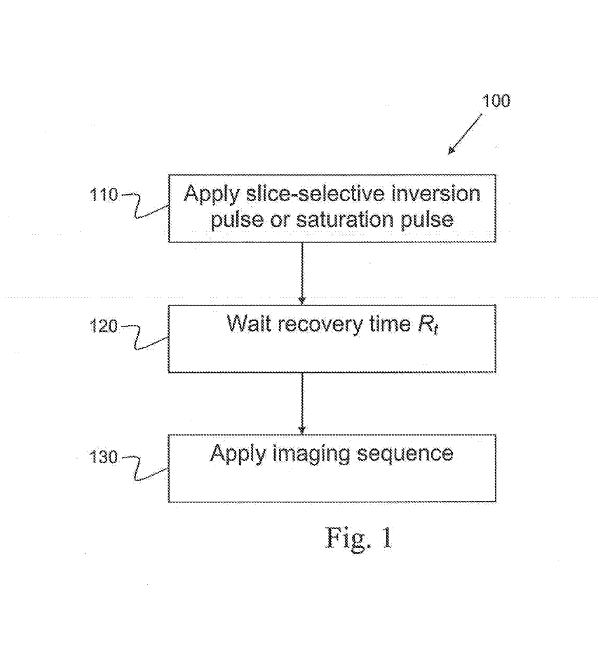

Reference is now made to FIG. 1, which presents an exemplary embodiment of a flowchart (100) giving a schematic outline of the steps for one pulse sequence of this method. During the “preparation” part (110) of a pulse sequence, at least one slice-selective inversion pulse or at least one saturation pulse is applied to a selected slice of the fluid. A recovery time Rₜ follows the preparation part (120), after which is the “readout” part, during which an imaging sequence (130) is applied to the selected slice.

This pulse sequence (100) (preparation part (110)—recovery time (120)—readout part (130)) is repeated at least once, preferably using different Rₜ values, more preferably for a series of Rₜ values. In some embodiments, the imaging sequence comprises at least two spatial encoding steps. The results from a set of repeated pulse sequences generate at least one 2D or 3D flow velocity profile of at least once slice of the fluid perpendicular to the flow.

In less-preferred embodiments of the invention, it can be necessary to wait for full relaxation of the spins between repetitions of the pulse sequence, which can be very time consuming, especially if the spin-lattice relaxation rate is small.

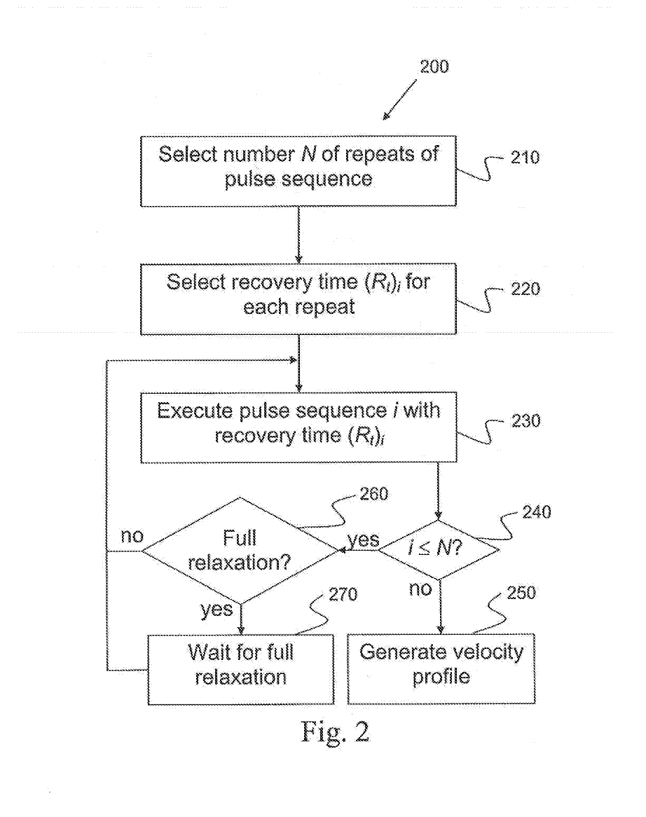

Reference is now made to FIG. 2, which shows and exemplary embodiment of a flowchart 200 giving a schematic outline of the steps for creating a velocity profile in a slice of the fluid. The number of repeats N (210), where N is greater than 1, and the recovery time (Rₜ)ᵢ for each repeat i (220) are selected. Then, for each repeat I, a pulse sequence is executed (230), using a procedure such as the exemplary procedure (100) outlined in FIG. 1, the pulse sequence having the recovery time (Rₜ)ᵢ. If the number of repeats executed, i, is greater than N (240), a velocity profile is generated (250) and the process terminates. If full relaxation is needed between pulse sequences (260), the system waits for full relaxation (270), then executes the next pulse sequence (230) using the next relaxation time (Rₜ)ᵢ₊₁. If full relaxation is not needed (260), the next pulse sequence is executed (230) without a waiting time using the next relaxation time (Rₜ)ᵢ₊₁.

In some preferred embodiments of the invention, the imaging sequence is a very short T_{E} standard SE sequence. In other preferred embodiments of the invention, the pulse sequence is an ultra-short T_{E} (UTE) sequence with spiral k-space sampling. In especially preferred embodiments of the invention, a UTE sequence with spiral k-space sampling is used, with segmentation to speed up image acquisition.

In the invention herein described, for any recovery time, the spins in the selected slice are divided into three populations, one which comprises spins that flowed into the slice during the recovery time Rₜ, one which comprises spins that resided in the slice for the whole of the recovery time Rₜ and which retain the magnetization imposed upon them during the preparation part, and one which comprises spins that resided in the slice for the whole of the recovery time Rₜ but are not magnetized. The fraction of the total population of spins which is in each magnetization state is F, S and S′, respectively. It should be noted that the population S′ includes both spins that were never magnetized and spins that have relaxed and lost magnetization since the start of the recovery period.

The time dependence of F is given by equation (1);

$$F = \{ \begin{matrix}\frac{v}{l} R \text{?} & R \text{?} < \frac{l}{v} \\ 1 & R \text{?} \geq \frac{l}{v}\end{matrix} \\ \text{?} \text{indicates text missing or illegible when filed} \qquad ( 1 )$$

where v is the velocity of the flow and l is the thickness of the slice. In practice, the fraction F will be slightly less than 1 when Rₜ=l/v, since some of the fluid is moving slower than v. As Rₜ increases, it approaches closer to 1.

Inverting the equation, the flow velocity can be determined from

$$v = \frac{Fl}{{R}_{t}} \qquad ( 2 )$$

The time dependence of S is given by equation (2) :

S=(1−F)(I−βe^{-R}^{ᵢ}^{R}^{ᵢ})

where (1−F) is the fraction of the spins that resided in the slice for the whole of the time i, (I−β) is the magnetization fraction in the slice immediately after the preparation part (110), and R₁ is the spin-lattice relaxation rate. Both β and R₁ can be measured independently in the absence of a flow.

From equation (2), F can be calculated from

$$F = 1 - \frac{S}{1 - β e \text{?}} \\ \text{?} \text{indicates text missing or illegible when filed} \qquad ( 4 )$$

Using the measured results, S, F and v can be found from the measured data using equations 2 and 4.

Since the model presented here can be applied separately and independently to each voxel in the image, the velocity v of the fluid in the volume of the voxel will be determined independently for each voxel, thereby creating the desired velocity profile.

### EXAMPLE

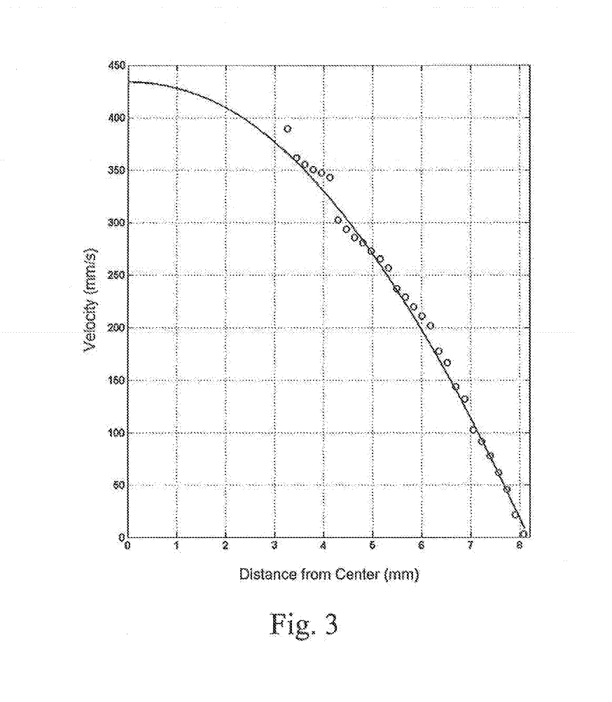

As a demonstration that the method herein disclosed can reproduce results obtained by standard methods, velocity profiles were obtained for glycerol flowing through a 16 mm diameter pipe by the method disclosed in the present invention and by a conventional method. The results are presented graphically in FIG. 3. Open circles indicate the velocity profile obtained by the method herein disclosed, and the velocity profile obtained by a conventional method is indicated by a solid line. As can be seen in the figure, the method disclosed herein accurately reproduces the flow velocity profile obtained by the conventional method, even at the outer edge of the pipe where the velocity approaches zero.

We claim:

1. An MRI-based method for determining a velocity profile for a fluid flowing through a pipe, said method comprising:
selecting a slice of said pipe through which said fluid is flowing;
selecting a pulse sequence comprising a preparation part and a readout part;
applying said preparation part to said slice;
waiting a predetermined time Rₜ; and
applying said readout part to said slice, said readout part comprising an imaging sequence
wherein said velocity profile is determinable from analysis of said imaging sequence.

2. The method according to claim 1, additionally comprising a step of selecting said imaging sequence selected from a group consisting of: a standard Spin Echo sequence, a very short T_{E} sequence, a UTE sequence with spiral k-space sampling, and a UTE sequence with spiral k-space sampling and segmentation.

3. The method according to claim 1, additionally comprising a step of determining said velocity for at least one volume within said slice according to
$$v = \frac{Fl}{{R}_{t}} ,$$
where F is a fraction of a population of spins in said slice that flowed into said slice during said time Rₜ and l is a thickness of said slice.

4. The method according to claim 1, additionally comprising a step of determining said velocity for at least one volume within said slice according to
$$v = \frac{Fl}{{R}_{t}} and F = 1 - \frac{S}{1 - β e \text{?}} , \\ \text{?} \text{indicates text missing or illegible when filed}$$
where F is a fraction of a population of spins in said slice that flowed into said slice during said time Rₜ, S is a fraction of a population of spins in said slice that resided in said slice for an entirety of said recovery time Rₜ and which retain a magnetization imposed upon them during said preparation part, l is a thickness of said slice, β is a magnetization fraction in said slice immediately after said preparation part, and R₁ is a spin-lattice relaxation rate.

5. The method according to claim 1, additionally comprising steps of (i) providing N said predetermined times (Rₜ)ᵢ, 1≦i≦N, and (ii) for each predetermined time (Rₜ)ᵢ, 1≦i≦N, executing said steps of applying said preparation part, waiting said predetermined time (Rₜ)ᵢ, and applying said readout part.

6. The method according to claim 1, wherein said pulse sequence provides a longitudinal magnetization and a transverse magnetization, and said method comprises encoding velocity information into said longitudinal magnetization.

7. The method according to claim 1, additionally comprising a step of applying said method to at least two slices of said fluid in said pipe.

8. The method according to claim 1, additionally comprising a step of selecting said velocity profile from a group consisting of a 2D profile and a 3D profile.

9. The method according to claim 1, wherein said fluid comprises drilling mud.
